(19) United States
(12) Patent Application Publication
(10) Pub. No.: US 2010/0224901 A1
(43) Pub. Date: Sep. 9, 2010

(54) SEMICONDUCTOR LIGHT-EMITTING DEVICE

(75) Inventors: Yoichi KUROKAWA, Miyagi-ken (JP); Hitoshi KITAGAWA, Miyagi-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/783,435

(22) Filed: May 19, 2010

Related U.S. Application Data
(63) Continuation of application No. PCT/JP2008/072076, filed on Dec. 4, 2008.

(30) Foreign Application Priority Data
Dec. 7, 2007 (JP) 2007-317365

(51) Int. Cl. H01L 33/40; H01L 33/00

(52) U.S. Cl. 257/98; 257/103; 257/E33.067; 257/E33.063

(57) ABSTRACT

A semiconductor light-emitting device includes an n-type semiconductor layer formed on a substrate, a light-emitting layer formed on the n-type semiconductor layer, a p-type semiconductor layer formed on the light-emitting layer, and an electrode layer formed on the p-type semiconductor layer. A through hole is formed in the electrode layer and filled with a dielectric layer. The dielectric layer is composed of a dielectric material having a dielectric constant such that the wavelength λₚ of surface plasmon is shorter than (λ₁>λₚ) the wavelength λ₁ of light emitted from the light-emitting layer and propagated through the semiconductor layer in order to cause both the p-type semiconductor layer side and the top side of the through hole to function as open ends of a resonator and enhance the efficiency of coupling between the surface plasmon and the light and increase the extinction cross-sectional area.

### CLAIM OF PRIORITY

This application is a Continuation of International Application No. PCT/JP2008/072076 filed on Dec. 4, 2008, which claims benefit of the Japanese Patent Application No. 2007-317365 filed on Dec. 7, 2007, both of which are hereby incorporated by reference.

### BACKGROUND OF THE INVENTION

1. Field of the Invention

The present invention relates to a semiconductor light-emitting device and particularly to a semiconductor light-emitting device with a light radiation efficiency enhanced by utilizing surface plasmon produced on a surface of an electrode layer.

2. Description of the Related Art

There have been known semiconductor light-emitting devices each including an n-type layer composed of single-crystal Si-doped GaN, an n-type cladding layer composed of single-crystal Si-doped Al0.1Ga0.9N, a light-emitting layer having a multiple quantum well structure (MQW), a protective layer composed of single-crystal undoped GaN, a p-type cladding layer composed of single-crystal Mg-doped Al0.1Ga0.9N, and a p-type contact layer composed of single-crystal Mg-doped Ga0.95In0.05N, which are formed on a (0001) plane of an N-type GaN substrate, and further including an electrode layer and a protective layer composed of SiO2 which are laminated in that order (refer to FIG. 4 of Japanese Unexamined Patent Application Publication No. 2005-108982). The electrode layer includes the two layers, i.e., a first electrode (ohmic electrode) composed of Pd and a second electrode composed of aluminum and formed on the first electrode. Each of the electrodes has a large number of circular holes periodically formed at predetermined intervals in a triangular lattice pattern. The protective layer is formed to cover the first electrode and the second electrode.

In the semiconductor light-emitting devices, when circular holes are formed in a triangular lattice pattern in the second electrode composed of a metal (aluminum) with a high plasma frequency, the dielectric constant periodically changes near the interface between the electrode layer and the p-type contact layer, and thus surface plasmon may be excited with light emitted in the MQW light-emitting layer. In addition, the excited surface plasmon is radiated as light from the surface of the protective layer. When the surface plasmon is excited, light at an angle of incidence larger than a critical angle which is determined by a ratio of the refractive index of the p-type contact layer to that of the protective layer is also radiated, thereby improving the efficiency of light radiation from the semiconductor light-emitting device.

### SUMMARY OF THE INVENTION

However, since the semiconductor light-emitting device described in Japanese Unexamined Patent Application Publication No. 2005-108982 uses, as a protective layer material, a dielectric material with a low dielectric constant, such as SiO2 or the like (the dielectric constant of SiO2 is 2.0 or less), enhancement of the light radiation efficiency of the semiconductor light-emitting device due to the effect of surface plasmon is limited by the principle of a resonator described below.

In addition, in the semiconductor light-emitting device described in Japanese Unexamined Patent Application Publication No. 2005-108982, a large number of circular holes are periodically formed in the electrode layer according to the excitation conditions of surface plasmon, for example, the dielectric constant of the electrode layer material, the dielectric constant of the protective layer material, the wavelength of light propagated through the p-type contact layer, and the like, and the formation period of the circular holes is determined with high precision. Thus, there is the problem that a large amount of labor is required for forming the electrode layer, thereby increasing the manufacturing cost of the semiconductor light-emitting device.

The present invention provides a semiconductor light-emitting device easy to manufacture, having a high light radiation efficiency, and using surface plasmon.

According to an embodiment of the present invention, a semiconductor light-emitting device includes a light-emitting layer, a semiconductor layer formed on the light-emitting layer, an electrode layer formed on the semiconductor layer, through holes formed in the electrode layer, and dielectric layers in contact with the inner surfaces of the through holes. The dielectric layers are composed of a dielectric material which has a dielectric constant satisfying a wavelength relation λ1>λp wherein λ1 represents the wavelength of light emitted from the light-emitting layer and propagated through the semiconductor layer, and λp represents the wavelength of surface plasmon excited by the light propagated through the semiconductor layer at the interface between the electrode layer and the dielectric layer on the inner surface of each of the through holes. In addition, the thickness of the electrode layer is a value which causes resonance of the surface plasmon excited with the light propagated through the semiconductor layer and reaching the electrode layer.

When the though holes are formed in the electrode layer, and the dielectric layers are formed in contact with the inner surfaces of the through holes, the surface plasmon excited with the light emitted from the light-emitting layer and propagated through the semiconductor layer is propagated along the inner surfaces of the through holes. When the relation between the wavelength of the surface plasmon and the thickness of the semiconductor layer satisfies resonance conditions, the through holes function as resonators. The characteristics of a resonator are represented by the three parameters including a Q value (ratio of the electromagnetic field energy localized in a resonator to the power of incident light taken in the resonator per period (time)), a mode volume (volume of a region in which the electromagnetic field energy may be localized in and around a resonator), and an extinction cross-sectional area (area of a range in which light is taken in the openings of the through holes). In order to enhance the light radiation efficiency of the semiconductor light-emitting device, a higher Q value, a smaller mode volume, and a larger extinction cross-sectional area are required.

In order to realize the above-mentioned conditions, it is thought to design a resonator to decrease the wavelength of surface plasmon. This is because the thickness of the electrode layer satisfying the resonance conditions is decreased, thereby decreasing the mode volume. Further, when the wavelength λp of surface plasmon is shorter than the wavelength λ1 of light emitted from the light-emitting layer and propagated through the semiconductor layer, both the inlet and outlet of a resonator function as open ends, and thus the efficiency of coupling of the surface plasmon and the light propagated through the semiconductor layer is improved, increasing the extinction cross-sectional area.

In order to decrease the wavelength of surface plasmon, it is though to increase the dielectric constant of the dielectric layers and decrease the radius of through holes. However, when the radius of the through holes is decreased, the extinction cross-sectional area is also decreased. Therefore, in order to enhance the efficiency of light radiation from the semiconductor light-emitting device, it is preferred to increase the dielectric constant of the dielectric layers so that λp is shorter than λ1 within a range in which the extinction cross-sectional area of the through holes is not extremely decreased.

A metal used as an electrode preferably has a negative value of dielectric constant with a large absolute value of real part and a small absorption effect, i.e., a dielectric constant with a small imaginary part value. The absorption effect of the metal of the electrode layer increases as the dielectric constant of the dielectric layer increases. Therefore, the dielectric constant is preferably as high as possible from the viewpoint of wavelength, but actually, it is necessary to select the dielectric material and the electrode material in view of balance with the absorption effect.

The thickness of the electrode layer is particularly preferably determined to cause primary resonance between the surface plasmon and the light propagated through the semiconductor layer and reaching the electrode layer. Although a plasmon resonator may utilize primary to higher-order resonances, the luminance of the semiconductor light-emitting device is further enhanced by primary resonance.

In the semiconductor light-emitting device according to the present invention, a plurality of the through holes may be formed in a planar direction of the electrode layer so as to be arranged aperiodically in the planar direction of the electrode layer.

As described above, in the semiconductor light-emitting device according to the present invention, surface plasmon is produced on the inner surfaces of the through holes. Therefore, the dimension between the through holes and the formation direction thereof need not be strictly regulated, thereby facilitating the formation of the electrode layer and decreasing the cost of the semiconductor light-emitting device. Of course, when a plurality of through holes are formed periodically or quasi-periodically, the light radiation efficiency of the semiconductor light-emitting device may be enhanced. Periodic formation permits the high-density formation of the through holes, and quasi-periodic formation permits the isotropic formation of the through holes.

In the semiconductor light-emitting device according to the present invention, red light is emitted from the light-emitting layer, and the main materials constituting the electrode layer and the dielectric layers are gold and TiO2 or silver and GaP, respectively.

In this configuration, the material combination is most suitable for enhancing the emission efficiency of red light in view of the relation between the plasmon wavelength and the absorption effect of the metal.

In the semiconductor light-emitting device according to the present invention, green light is emitted from the light-emitting layer, and the main materials constituting the electrode layer and the dielectric layers are silver and TiO2 or aluminum and GaP, respectively.

In this configuration, the material combination is most suitable for enhancing the emission efficiency of green light.

In the semiconductor light-emitting device according to the present invention, blue light is emitted from the light-emitting layer, and the main materials constituting the electrode layer and the dielectric layers are silver and GaN or aluminum and GaP, respectively.

In this configuration, the material combination is most suitable for enhancing the emission efficiency of blue light.

### BRIEF DESCRIPTION OF THE DRAWINGS

FIG. 1 is a perspective view showing a laminated structure of a semiconductor light-emitting device according to an embodiment of the present invention;

FIG. 2 is a graph showing a dispersion relation between the number vector of surface plasmon and light frequency and a relation between the thickness of an electrode layer and resonance condition of plasmon propagated through a dielectric layer;

FIG. 3 is a graph showing the radiation efficiency of a semiconductor light-emitting device according to an embodiment of the present invention; and

FIG. 4 is a graph showing the radiation efficiency of a semiconductor light-emitting device according to an embodiment of the present invention.

### DESCRIPTION OF THE PREFERRED EMBODIMENTS

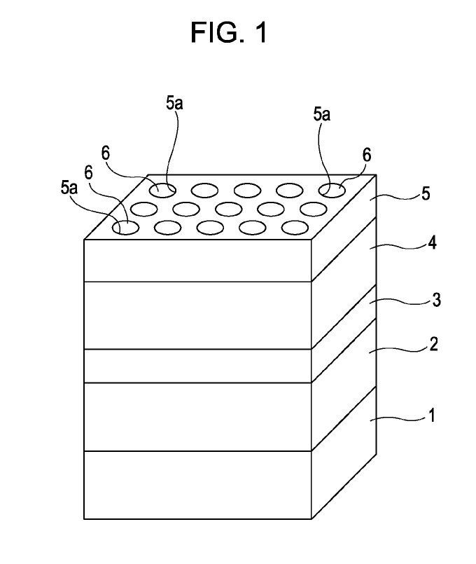

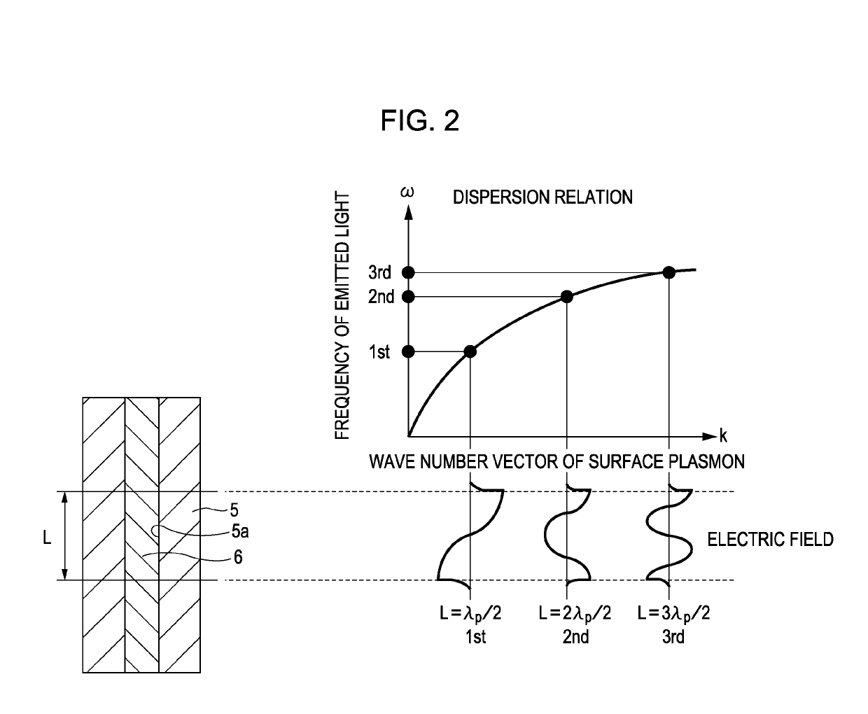

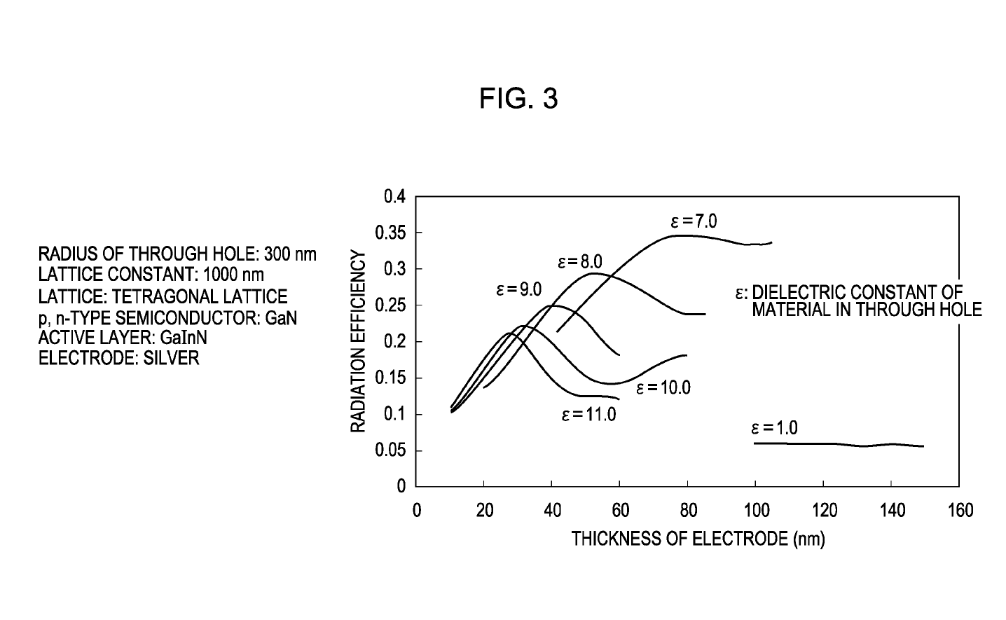

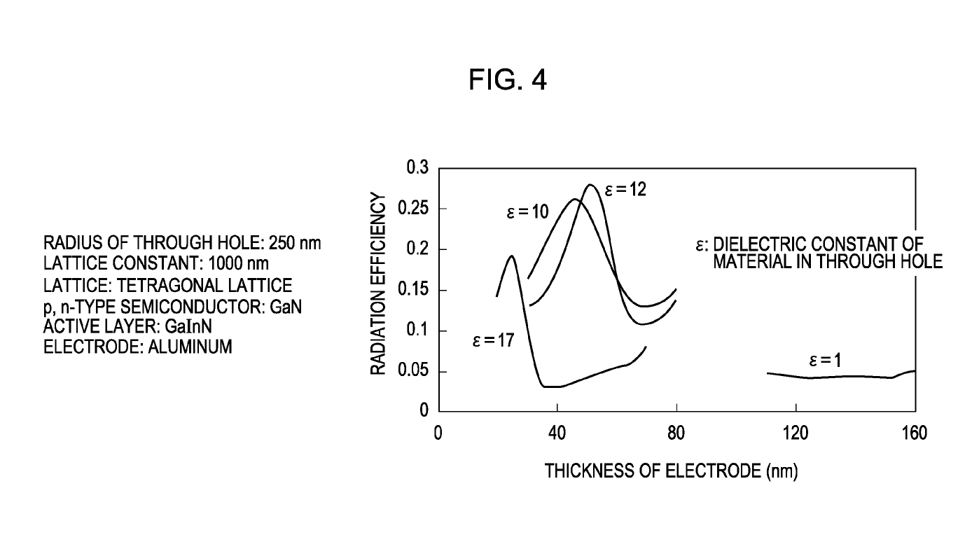

A semiconductor light-emitting device according to an embodiment of the present invention is described below on the basis of FIGS. 1 to 4. FIG. 1 is a perspective view showing a laminated structure of a semiconductor light-emitting device according to an embodiment of the present invention. FIG. 2 is a graph showing a relation between the thickness of an electrode layer and condition of resonance between surface plasmon and light emitted from a light-emitting layer and propagated through a dielectric layer. FIGS. 3 and 4 are each a graph showing the radiation efficiency of a semiconductor light-emitting device according to an embodiment of the present invention.

As shown in FIG. 1, a semiconductor light-emitting device according to an embodiment of the present invention includes an n-type semiconductor layer 2 formed on a substrate 1, a light-emitting layer 3 formed on the n-type semiconductor layer 2, a p-type semiconductor layer 4 formed on the light-emitting layer 3, an electrode layer 5 formed on the p-type semiconductor layer 4, through holes 5a formed in the electrode layer 5, and dielectric layers 6 filled in the through holes 5a. As the substrate, the n-type semiconductor layer 2, the light-emitting layer 3, and the p-type semiconductor layer 4, any known layers may be used. For example, the layers described in Japanese Unexamined Patent Application Publication No. 2005-108982 may be used.

The electrode layer 5 is formed using a metallic material which easily produces a larger effect of surface plasmon, for example, silver, aluminum, gold, or the like. The electrode layer 5 is formed to a thickness which causes resonance, particular preferably primary resonance, between surface plasmon and light emitted from the light-emitting layer 3 and propagated through the p-type semiconductor layer 4 and reaching the electrode layer 5. Specifically, as shown in FIG. 2, when L=λp/2 wherein L represents the thickness of the electrode layer 5, and λp represents the wavelength of surface plasmon, primary resonance may be produced between the surface plasmon and the light emitted from the light-emitting layer 3 and propagated through the p-type semiconductor layer 4 and reaching the electrode layer 5. In addition, when the thickness of the electrode layer 5 satisfies L=2λp/2, secondary resonance may be produced, and when the thickness of the electrode layer 5 satisfies L=3λp/2, tertiary resonance may be produced. A graph shown at the upper right of FIG. 2 shows a dispersion relation between the number vector of surface plasmon propagated on the side surfaces of the dielectric layers 6 and the frequency of light. In this graph, the number vector k of surface plasmon is shown in the abscissa, and the frequency w of light emitted from the light-emitting layer 3 and propagated through the dielectric layers 6 is shown in the ordinate. Namely, points on a solid line in the graph denote values actually present as the number vector k of surface plasmon and the frequency ω of light. The dispersion relation, i.e., the wavelength λp of surface plasmon is determined by a combination of a metal and a dielectric material in contact with the metal.

Japanese Unexamined Patent Application Publication No. 2005-108982 utilizes a periodic structure (may be formed by through holes, needle-like projections, or the like) formed in an electrode layer. However, in the present invention, the dielectric constant of the dielectric layers 6 in contact with the inner surfaces of the through holes 5a formed in the electrode layer 5 is controlled so that resonance of surface plasmon occurs at the interfaces between the electrode layer 5 and the dielectric layers 6 in contact with the electrode layer 5. Therefore, the light radiation efficiency may be increased only by forming at least one through hole 5a in the electrode layer 5. However, it is practically difficult to achieve sufficient luminance by forming only one through hole 5a, and thus the through holes 5a are practically formed in as large number as possible in the electrode layer 5. When a plurality of through holes 5a are formed in the electrode layer 5, each of the through holes 5a functions as a resonator, and thus the plurality of through holes 5a need not be formed in a periodic structure such as a triangular lattice or tetragonal lattice pattern or the like. The plurality of through holes 5a may be formed in a quasi-periodic structure which is rotationally symmetric or a random structure without periodicity. In addition, when the plurality of through holes 5a are periodically arranged, the magnitude of reciprocal lattice vector need not be strictly regulated. Therefore, it is very easy to manufacture the electrode layer 5 and eventually the semiconductor light-emitting device.

In each of the dielectric layers 6, both the p-type semiconductor layer-side surface and the top surface of each of the through holes 5a function as open ends of a resonator. In addition, the dielectric layers 6 are formed using a dielectric material having a dielectric constant such that the wavelength λp of surface plasmon is shorter (λ1>λp) than the wavelength λ1 of light emitted from the light-emitting layer 3 and propagated through the dielectric layers 6 in order to enhance the efficiency of coupling between the surface plasmon and the light propagated through the p-type semiconductor layer 4 and to increase the extinction cross-sectional area. The wavelength λp surface plasmon depends not only on the dielectric constant of the dielectric material constituting the dielectric layers 6 but also on the diameter of the through holes 5a. Therefore, the dielectric material used is determined by a relation to the diameter of the through holes 5a.

The thickness of the electrode layer 5, which causes primary resonance, and the mode volume may be decreased by using a dielectric material having a higher dielectric constant ε1 as the dielectric material constituting the dielectric layers 6, but the light absorbing effect of the metal is increased. In contrast, the light absorbing effect of the metal may be decreased by using a dielectric material having a lower dielectric constant ε1, but the thickness of the electrode layer 5, which causes primary resonance, and the mode volume are increased.

FIG. 3 is a graph showing the radiation efficiency of a semiconductor light-emitting device which emits green light and which has a structure in which the through holes 5a having a radius of 300 nm are arranged in a tetragonal lattice pattern with a lattice constant of 1000 nm in a silver thin film. This graph shows that the radiation efficiency is maximized when the dielectric constant in the through holes 5a is 7 to 8. FIG. 4 is a graph showing the radiation efficiency of a semiconductor light-emitting device which emits green light and which has a structure in which the through holes 5a having a radius of 250 nm are arranged in a tetragonal lattice pattern with a lattice constant of 1000 nm in an aluminum thin film. This graph shows that the radiation efficiency is maximized when the dielectric constant in the through holes 5a is 10 to 12.

Therefore, it is found that there is an optimum combination of the metal used for the electrode and the dielectric material filled in the through holes 5a. Namely, the materials constituting the dielectric layers 6 and the electrode layer 5 are selected from combinations which may enhance the efficiency of light radiation from the semiconductor light-emitting device according to the wavelength of the emitted light.

Specifically, in a semiconductor light-emitting device which emits red light, when gold is selected for the electrode, a titanium oxide with a dielectric constant of about 8.0, for example, TiO2 or the like, is preferred, while when silver is selected for the electrode, GaP or the like with a dielectric constant of about 11.0 is preferred. In a semiconductor light-emitting device which emits green light, when silver is selected for the electrode, a titanium oxide with a dielectric constant of about 8.0, for example, TiO₂ or the like, is preferred, while when aluminum is selected for the electrode, GaP or the like with a dielectric constant of about 12.0 is preferred. In a semiconductor light-emitting device which emits blue light, when silver is selected for the electrode, GaN with a dielectric constant of about 6.0 is preferred, while when aluminum is selected for the electrode, GaP or the like with a dielectric constant of about 14.0 is preferred. These are summarized as in Table 1.

TABLE 1

| Red | | Green | | Blue | |
|---|---|---|---|---|---|
| Electrode | Dielectric | Electrode | Dielectric | Electrode | Dielectric |
| (metal) | material | (metal) | material | (metal) | material |
| Gold (Au) | TiO₂ | Silver | TiO₂ | Silver (Ag) | GaN |
| | | (Ag) | | | |
| Silver | GaP | Aluminum | GaP | Aluminum | GaP |
| (Ag) | | (Al) | | (Al) | |

It is sufficient to provide the dielectric layers 6 in contact with at least the inner surfaces of the through holes. However, for the sake of easy manufacture, the dielectric layers 6 may be filled in the through holes 5a or may be formed not only to be filled in the through holes but also to cover the whole surface of the electrode layer 5.

What is claimed is:

1. A semiconductor light-emitting device comprising:
a light-emitting layer;
a semiconductor layer formed on the light-emitting layer;
an electrode layer formed on the semiconductor layer;
a through hole formed in the electrode layer; and
a dielectric layer in contact with the inner surface of the through hole;
wherein the dielectric layer is composed of a dielectric material having a dielectric constant satisfying a wavelength relation λ₁>λₚ wherein λ₁ represents the wavelength of light emitted from the light-emitting layer and propagated through the semiconductor layer, and λₚ represents the wavelength of surface plasmon excited by the light propagated through the semiconductor layer at the interface between the electrode layer and the dielectric layer on the inner surface of the through hole; and
the thickness of the electrode layer is a value which causes resonance of the surface plasmon excited with the light propagated through the semiconductor layer and reaching the electrode layer.

2. The semiconductor light-emitting device according to claim 1, wherein a plurality of the through holes are formed in a planar direction of the electrode layer so as to be arranged aperiodically in the planar direction of the electrode layer.

3. The semiconductor light-emitting device according to claim 1, wherein red light is emitted from the light-emitting layer, and the main materials constituting the electrode layer and the dielectric layer are gold and TiO₂ or silver and GaP, respectively.

4. The semiconductor light-emitting device according to claim 1, wherein green light is emitted from the light-emitting layer, and the main materials constituting the electrode layer and the dielectric layer are silver and TiO₂ or aluminum and GaP, respectively.

5. The semiconductor light-emitting device according to claim 1, wherein blue light is emitted from the light-emitting layer, and the main materials constituting the electrode layer and the dielectric layer are silver and GaN or aluminum and GaP, respectively.
